(19) United States
(12) Patent Application Publication
(10) Pub. No.: US 2025/0079309 A1
(43) Pub. Date: Mar. 6, 2025

(54) WRAP-AROUND MIDDLE-OF-LINE CONTACT WITH BACKSIDE SOURCE/DRAIN CUT FOR DIRECT CONTACT AND BACKSIDE POWER DELIVERY NETWORK

(71) Applicant: International Business Machines Corporation, Armonk, NY (US)

(72) Inventors: Lijuan Zou, Slingerlands, NY (US); Tao Li, Slingerlands, NY (US); Ruilong Xie, Niskayuna, NY (US); Chanro Park, Clifton Park, NY (US)

(21) Appl. No.: 18/458,426

(22) Filed: Aug. 30, 2023

(51) Int. Cl. H01L 23/528; H01L 21/768; H01L 21/8234; H01L 29/08; H01L 29/417

(52) U.S. Cl. CPC H01L 23/5286; H01L 21/76897; H10D 30/6729; H10D 62/151; H10D 84/013; H10D 84/0149; H10D 84/038; H10D 30/014; H10D 30/43; H10D 30/6735; H10D 30/6757; H10D 62/121; H10D 84/0128

(57) ABSTRACT

A semiconductor device fabrication method is provided and includes executing front-end-of-line (FEOL) processing to form first and second source/drain (S/D) epitaxy, forming a middle-of-line (MOL) contact to the first S/D epitaxy, executing a self-aligned backside S/D cut to form an opening in which respective sides of each of the first and second S/D epitaxy are exposed, depositing metallic material along the respective sides of each of the first and second S/D epitaxy in the opening and forming silicide from the metallic material whereby the silicide at the first S/D epitaxy contacts the MOL contact and the sides of the first S/D epitaxy.

### BACKGROUND

The present invention generally relates to fabrication methods and resulting structures for semiconductor devices. More specifically, the present invention relates to a method and structure to form a wrap-around middle-of-line (MOL) contact with a backside source/drain (S/D) cut for direct contact and backside power delivery network (BSPDN).

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

According to an aspect of the invention, a semiconductor device fabrication method is provided. A non-limiting example of the semiconductor device fabrication method includes executing front-end-of-line (FEOL) processing to form first and second source/drain (S/D) epitaxy, forming a middle-of-line (MOL) contact to the first S/D epitaxy, executing a self-aligned backside S/D cut to form an opening in which respective sides of each of the first and second S/D epitaxy are exposed, depositing metallic material along the respective sides of each of the first and second S/D epitaxy in the opening and forming silicide from the metallic material whereby the silicide at the first S/D epitaxy contacts the MOL contact and the sides of the first S/D epitaxy. Additionally or alternatively, the silicide provides for improved and more reliable conductivity.

In embodiments, the MOL contact is a gouged contact. Additionally or alternatively, the MOL being a gouged contact provides for improved and more reliable conductivity.

In embodiments, the semiconductor device fabrication method further includes executing a self-aligned backside cut toward the second S/D epitaxy. Additionally or alternatively, the backside cut provides for the formation of a backside contact.

In embodiments, the self-aligned backside cut includes gouging into the second S/D epitaxy. Additionally or alternatively, the gouging into the second epitaxy provides for the backside contact being a gouged contact and thus an improved and more reliable contact.

In embodiments, the semiconductor device fabrication method further includes executing backside contact metallization to form a backside contact in contact with the second S/D epitaxy. Additionally or alternatively, the backside contact provides for additional backside connections.

In embodiments, the semiconductor device fabrication method further includes forming a backside power rail (BPR) in contact with the backside contact and forming a backside power distribution network (BSPDN) in contact with the BPR. Additionally or alternatively, the BPR and the BSPDN provide for additional power distribution.

According to an aspect of the invention, a semiconductor device fabrication method is provided. A non-limiting example of the semiconductor device fabrication method includes executing front-end-of-line (FEOL) processing to form first and second source/drain (S/D) epitaxy, forming a middle-of-line (MOL) contact to the first S/D epitaxy, executing a self-aligned backside S/D cut to form an opening in which respective sides of each of the first and second S/D epitaxy are exposed, selectively etching the respective sides of each of the first and second S/D epitaxy to recess the respective sides of each of the first and second S/D epitaxy, depositing metallic material along the respective sides of each of the first and second S/D epitaxy and forming silicide from the metallic material whereby the silicide at the first S/D epitaxy contacts the MOL contact and the sides of the first S/D epitaxy. Additionally or alternatively, the silicide provides for improved and more reliable conductivity.

In embodiments, the MOL contact is a gouged contact. Additionally or alternatively, the MOL being a gouged contact provides for improved and more reliable conductivity.

In embodiments, the semiconductor device fabrication method further includes executing a self-aligned backside cut toward the second S/D epitaxy. Additionally or alternatively, the backside cut provides for the formation of a backside contact.

In embodiments, the self-aligned backside cut includes gouging into the second S/D epitaxy. Additionally or alternatively, the gouging into the second epitaxy provides for the backside contact being a gouged contact and thus an improved and more reliable contact.

In embodiments, the semiconductor device fabrication method further includes executing backside contact metallization to form a backside contact in contact with the second S/D epitaxy and the silicide at the second S/D epitaxy contacts the backside contact and the sides of the second S/D epitaxy. Additionally or alternatively, the backside contact provides for additional backside connections.

In embodiments, the semiconductor device fabrication method further includes forming a backside power rail (BPR) in contact with the backside contact and forming a backside power distribution network (BSPDN) in contact with the BPR. Additionally or alternatively, the BPR and the BSPDN provide for additional power distribution.

According to an aspect of the invention, a semiconductor device is provided. A non-limiting example of the semiconductor device includes first and second source/drain (S/D) epitaxy, a middle-of-line (MOL) contact disposed in contact with the first S/D epitaxy and silicide formed along respective sides of each of the first and second S/D epitaxy. The silicide at the first S/D epitaxy is disposed in contact with the MOL contact and the sides of the first S/D epitaxy. Additionally or alternatively, the silicide provides for improved and more reliable conductivity.

In embodiments, the MOL contact is a gouged contact. Additionally or alternatively, the MOL being a gouged contact provides for improved and more reliable conductivity.

In embodiments, a backside placeholder element is in contact with the first S/D epitaxy. Additionally or alternatively, the placeholder element allows for further device components to be built.

In embodiments, a backside contact is disposed in contact with the second S/D epitaxy. Additionally or alternatively, the backside contact provides for additional backside connections.

In embodiments, the backside contact is a gouged contact. Additionally or alternatively, with the backside contact being a gouged contact, the backside contact provides for an improved and more reliable contact.

In embodiments, the backside contact cuts through shallow trench isolation (STI). Additionally or alternatively, the backside contact is isolated from other conductors.

In embodiments, the respective sides of each of the first and second S/D epitaxy are recessed from an original width and the silicide at the second S/D epitaxy is disposed in contact with the backside contact and the sides of the second S/D epitaxy.

In embodiments, the semiconductor device further includes a backside power rail (BPR) disposed in contact with the backside contact and a backside power delivery network (BSPDN) disposed in contact with the BPR. Additionally or alternatively, the BPR and the BSPDN provide for additional power distribution.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a flow diagram illustrating a semiconductor device fabrication method in accordance with one or more embodiments of the present invention;

FIG. 2 is a flow diagram illustrating a semiconductor device fabrication method in accordance with one or more embodiments of the present invention

FIG. 3 is a top-down view of a semiconductor device assembly being fabricated in accordance with one or more embodiments of the present invention;

FIG. 4 is a side view of a semiconductor device assembly in an initial stage of being fabricated in accordance with one or more embodiments of the present invention;

FIG. 5 is a side view of a semiconductor device assembly in a secondary stage of being fabricated following a self-aligned backside cut executed with respect to the semiconductor device assembly of FIG. 4 in accordance with one or more embodiments of the present invention;

FIG. 6 is a side view of a semiconductor device assembly in a third stage of being fabricated following metal deposition and silicide formation executed with respect to the semiconductor device assembly of FIG. 5 in accordance with one or more embodiments of the present invention;

FIG. 7 is a side view of a semiconductor device assembly in a fourth stage of being fabricated following dielectric fill executed with respect to the semiconductor device assembly of FIG. 6 in accordance with one or more embodiments of the present invention;

FIG. 8 is a side view of a semiconductor device assembly in a fifth stage of being fabricated following a self-aligned backside cut executed with respect to the semiconductor device assembly of FIG. 7 in accordance with one or more embodiments of the present invention;

FIG. 9 is a side view of a semiconductor device assembly in a sixth stage of being fabricated following placeholder removal and gouging executed with respect to the semiconductor device assembly of FIG. 8 in accordance with one or more embodiments of the present invention;

FIG. 10 is a side view of a semiconductor device in a final stage of being fabricated following backside contact formation and formations of a backside power rail (BPR) and a backside power delivery network (BSPDN) executed with respect to the semiconductor device assembly of FIG. 9 in accordance with one or more embodiments of the present invention; and

FIG. 11 is a side view of a semiconductor device in a final stage of being fabricated following backside contact formation and formations of a backside power rail (BPR) and a backside power delivery network (BSPDN) executed with respect to the semiconductor device assembly of FIG. 9 where S/D epitaxy has been recessed in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, field effect transistors (FETs) include doped source/drain regions that are formed in a semiconductor and separated by a channel region. A gate insulation layer is positioned about the channel region and a conductive gate electrode is positioned over or about the gate insulation layer. The gate insulation layer and the gate electrode together may be referred to as the gate stack for the device. By applying an appropriate voltage to the gate electrode, the channel region becomes conductive and current is allowed to flow from the source region to the drain region.

To improve the operating speed of the FETs, and to increase the density of FETs on an integrated circuit (IC), designs have gradually become smaller in size. Reductions to the size and the channel length in FETs can improve the switching speed of the FETs.

A number of challenges arise as feature sizes of FETs and ICs get smaller. For example, significant downsizing of traditional FETs may produce electrostatic issues and mobility degradation. Scaled-down FETs may have shorter gate lengths that make it more difficult to control the channel. Device architectures such as “gate-all-around” active nanostructures allow further scaling of ICs, in part, because the gate is structured to wrap around the channel, creating more surface area and better control. This structure can provide better control with lower leakage current, faster operations, and lower output resistance. Active nanostructures used to form the channel can include a semiconductor nanowire, i.e., a vertically or horizontally oriented thin wire, or a plurality of stacked nanosheets, i.e., a plurality of vertically spaced semiconductor sheets.

An additional challenge with size reductions in FETs and ICs is that, for front-end-of-line (FEOL) processing, there is little room for epitaxial merging. BSPDN structures, on the other hand, offer new opportunities for self-aligned backside contact cuts to address the issue of tight spaces for epitaxial merging. This is because it becomes possible to scale cell height continuously and to improve MOL-to-S/D contacts as well.

Turning now to an overview of the aspects of the invention, one or more embodiments of the invention address the above-described shortcomings of the prior art by providing a semiconductor device with frontside and backside contacts. The backside contact is a self-aligned backside contact cutting through S/D epitaxy of two FETs and through shallow trench isolation (STI) between the two FETs. Boundaries between the S/D epitaxy and the self-aligned backside contact includes silicide. At least an MOL-to-S/D gouged contact is connected to at least one side of the silicide to form a wrap-around contact and at least one backside S/D epitaxy is connected to the self-aligned backside contact.

The above-described aspects of the invention address the shortcomings of the prior art by providing for a semiconductor device fabrication method that includes executing front-end-of-line (FEOL) processing to form first and second source/drain (S/D) epitaxy, forming a middle-of-line (MOL) contact to the first S/D epitaxy, executing a self-aligned backside S/D cut to form an opening in which respective sides of each of the first and second S/D epitaxy are exposed, depositing metallic material along the respective sides of each of the first and second S/D epitaxy in the opening and forming silicide from the metallic material whereby the silicide at the first S/D epitaxy contacts the MOL contact and the sides of the first S/D epitaxy.

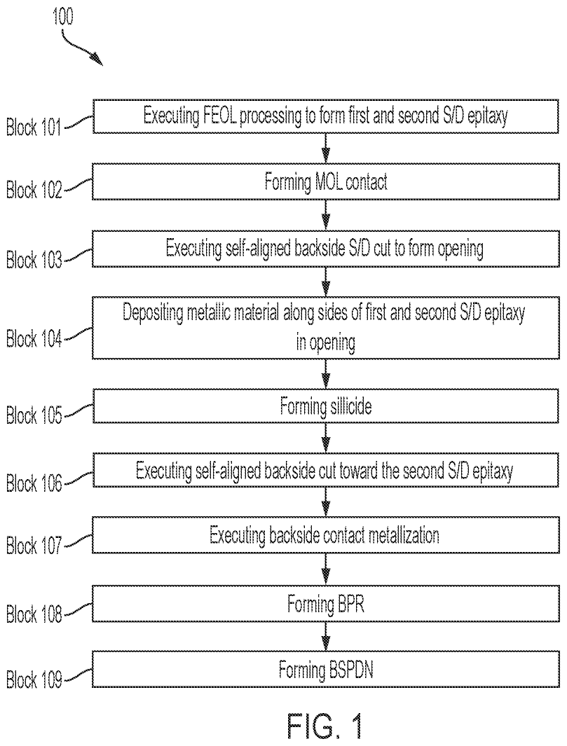

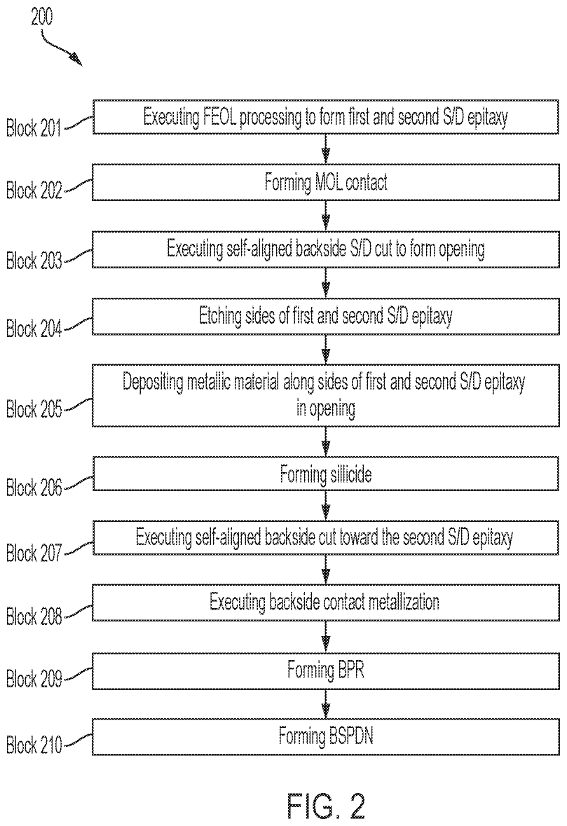

Turning now to a more detailed description of aspects of the present invention, FIGS. 1 and 2 depict semiconductor device fabrication methods 100 and 200, respectively.

As shown in FIG. 1, the semiconductor device fabrication method 100 includes executing FEOL processing to form first and second S/D epitaxy (block 101), forming an MOL contact, such as an MOL gouged contact, to the first S/D epitaxy (block 102), executing a self-aligned backside S/D cut to form an opening in which respective sides of each of the first and second S/D epitaxy are exposed (block 103), depositing metallic material along the respective sides of each of the first and second S/D epitaxy in the opening (block 104) and forming silicide from the metallic material whereby the silicide at the first S/D epitaxy contacts the MOL contact and the sides of the first S/D epitaxy (block 105).

In addition, the semiconductor device fabrication method 100 can include executing a self-aligned backside cut toward (and into, by gouging) the second S/D epitaxy (block 106), executing backside contact metallization to form a backside contact in contact with the second S/D epitaxy (block 107), forming a backside power rail (BPR) in contact with the backside contact (block 108) and forming a backside power distribution network (BSPDN) in contact with the BPR (block 109).

As shown in FIG. 2, the semiconductor device fabrication method 200 includes executing FEOL processing to form first and S/D epitaxy (block 201), forming an MOL contact, such as an MOL gouged contact, to the first S/D epitaxy (block 202), executing a self-aligned backside S/D cut to form an opening in which respective sides of each of the first and second S/D epitaxy are exposed (block 203), selectively etching the respective sides of each of the first and second S/D epitaxy to recess the respective sides of each of the first and second S/D epitaxy (block 204), depositing metallic material along the respective sides of each of the first and second S/D epitaxy (block 205) and forming silicide from the metallic material whereby the silicide at the first S/D epitaxy contacts the MOL contact and the sides of the first S/D epitaxy (block 206).

In addition, the semiconductor device fabrication method 200 can include executing a self-aligned backside cut toward (and into, by gouging) the second S/D epitaxy (block 207), executing backside contact metallization to form a backside contact in contact with the second S/D epitaxy whereby the silicide at the second S/D epitaxy contacts the backside contact and the sides of the second S/D epitaxy (block 208), forming a backside power rail (BPR) in contact with the backside contact (block 209) and forming a backside power distribution network (BSPDN) in contact with the BPR (block 210).

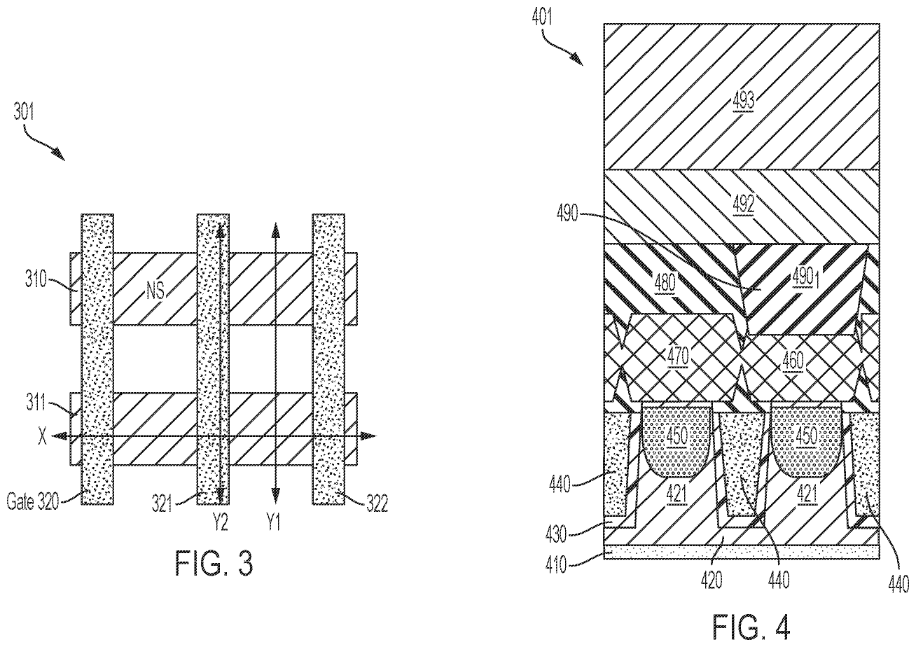

With continued reference to FIGS. 1 and 2 and with additional reference to FIG. 3 and to FIGS. 4-11, the semiconductor device fabrication methods 100 and 200 of FIGS. 1 and 2, respectively, will now be described in greater detail.

FIG. 3 depicts a top-down view of a semiconductor device assembly 301 that is being fabricated. The semiconductor device assembly 301 includes nanosheet channel regions 310 and 311 and gate regions 320, 321 and 322 extending across the nanosheet channel regions 310 and 311. For reference, the “Y1” cross-sectional cut line of FIG. 3 corresponds to the perspective of the images in FIGS. 4-11.

With reference to FIG. 4, a semiconductor device assembly 401 is provided in an initial stage of being fabricated following initial FEOL processing, subsequent MOL and back-end-of-line (BEOL) processing and carrier wafer bonding all of which are followed by a wafer flip operation and a substrate removal that stops on an etch stop layer. The semiconductor device assembly 401 thus includes an etch stop layer 410, a substrate 420, which formed of silicon or another suitable semiconductor material and which has pedestals 421, STI liner material 430 disposed over the substrate 420 and the pedestals 421 and STIs 440 interposed between the pedestals 421. The semiconductor device assembly 401 further includes placeholders 450 disposed on the pedestals 421, first and second S/D epitaxy 460 and 470 respectively disposed above the placeholders 450 and interlayer dielectric (ILD) 480 surrounding the first and second S/D epitaxy 460 and 470. In addition, the semiconductor device assembly 401 includes a frontside contact 490 extending through the ILD 480 to the first S/D epitaxy 460, a BEOL layer 492 disposed over the ILD 480 and in contact with the frontside contact 490 and a carrier wafer 493 disposed over the BEOL layer 492.

In accordance with embodiments, the frontside contact 490 can be provided as an MOL gouged and, in some cases, wraparound contact 4901. The following description will relate to the frontside contact 490 as being the MOL gouged wraparound contact but will refer to it as a frontside contact 490 for the purposes of clarity and brevity.

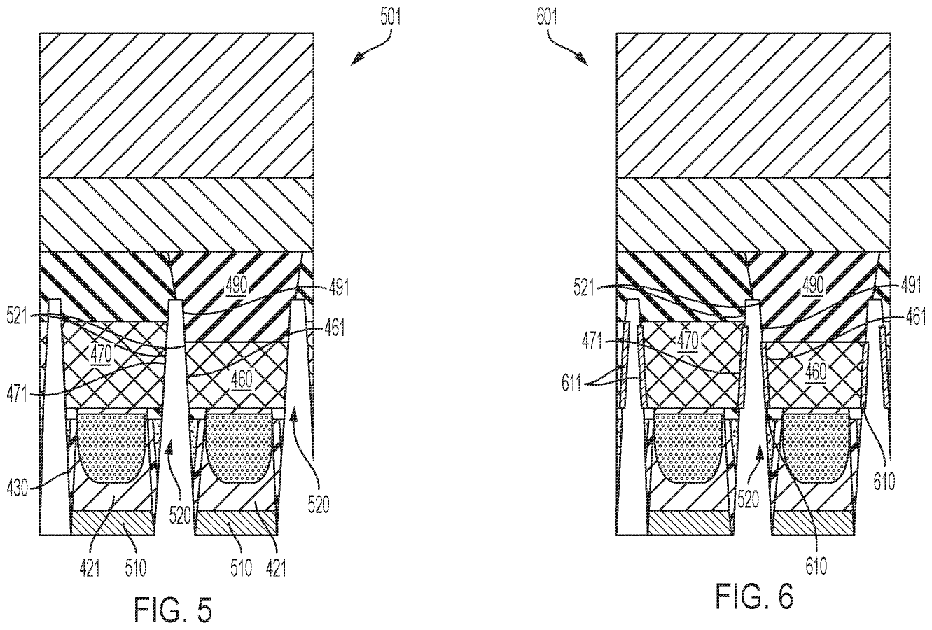

With continued reference to FIG. 4 and with additional reference to FIG. 5, a semiconductor device assembly 501 is provided in a secondary stage of being fabricated following removal of the etch stop layer 410, recession of the substrate 420 to a height defined above respective bottom portions of the STIs 440, cap dielectric deposition and chemical mechanical polishing (CMP) to form a cap 510 that is coplanar with the lowermost surface of the STI liner material 430 and a self-aligned backside cut executed with respect to the semiconductor device assembly 401 of FIG. 4. The self-aligned backside cut forms at least an opening 520 between the pedestals 421, through the STIs 440 and the ILD 480, between and through the first and second S/D epitaxy 460 and 470 and into the frontside contact 490. The opening 520 has opposing sides 521 by which respective sides 461 and 471 of the first and second S/D epitaxy 461 and 470, respectively, are exposed and by which a side 491 of the frontside contact 490 is exposed.

In accordance with embodiments, the self-aligned backside cut can be executed as a two-stage etch (e.g., stage 1: self-aligned backside cut land over HfO2 and backside of gate cut and stage 2: selective S/D etch to HfO2 and gate cut material such as SF6, CH2F2 or SF6, O2). In addition, to the extent that the self-aligned backside cut is executed such that an additional opening is formed in gate region 321 (i.e., “Y2” cross-sectional cut line in FIG. 3), the additional opening can be filled in with dielectric material to reduce parasitic capacitance.

With continued reference to FIG. 5 and with additional reference to FIG. 6, a semiconductor device assembly 601 is provided in a third stage of being fabricated following metal deposition, silicide formation and unreacted metal strip-off executed with respect to the semiconductor device assembly 501 of FIG. 5. The metal deposition results in metallic material being deposited along the opposing sides 521 of the opening 520 and the silicide formation results in the metallic material forming silicide 610, 611 along the opposing sides 521. At the first S/D epitaxy 460, the silicide 610 extends along at least the side 461 of the first S/D epitaxy 460 and is in contact with a bottom portion of the side 491 of the frontside contact 490. The silicide 610 thus provides for improved and more reliable electrical contact between the frontside contact 490 and the first S/D epitaxy 460. At the second S/D epitaxy 470, the silicide 611 extends along at least the side 471 of the second S/D epitaxy 470 and is thus positioned to provide for improved and more reliable electrical contact between the second S/D epitaxy 470 and a backside contact to be described below.

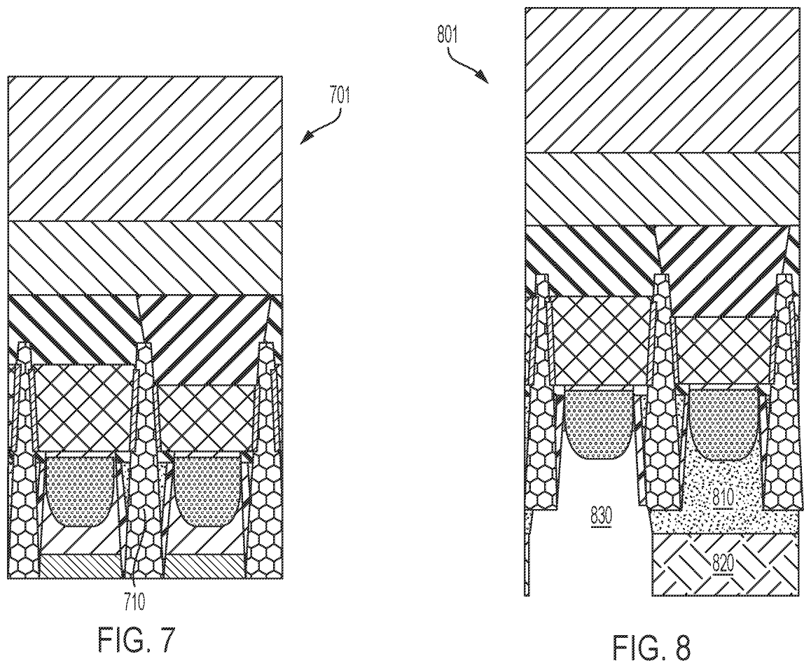

With continued reference to FIG. 6 and with additional reference to FIG. 7, a semiconductor device assembly 701 is provided in a fourth stage of being fabricated following dielectric fill executed with respect to the semiconductor device assembly 601 of FIG. 6. The dielectric fill operation results in the opening 520 (see FIG. 6) being filled with dielectric fill material 710. As noted above, to the extent that the self-aligned backside cut is executed such that the additional opening is formed in the gate region 321 (i.e., “Y2” cross-sectional cut line in FIG. 3), the dielectric fill material 710 in this additional opening can reduce parasitic capacitance.

With continued reference to FIG. 7 and with additional reference to FIG. 8, a semiconductor device assembly 801 is provided in a fifth stage of being fabricated following, removal of the cap 510 (see FIG. 5), removal of remaining material of the substrate 420 (see FIG. 4), backside ILD deposition and planarization to form backside ILD 810, backside contact patterning to form a backside mask 820 and a self-aligned backside cut executed with respect to the semiconductor device assembly 701 of FIG. 7. The backside cut can be executed as a selective backside ILD etch to the STI liner material 430 and a backside S/D cut dielectric operation, which are enabled by selectivity between the backside ILD 810 and the STI liner material 430, to form a backside opening 830.

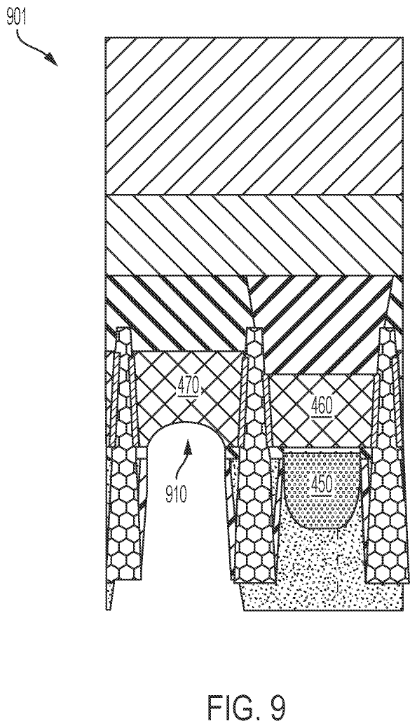

With continued reference to FIG. 8 and with additional reference to FIG. 9, a semiconductor device assembly 901 is provided in a sixth stage of being fabricated following placeholder removal and optional gouging executed with respect to the semiconductor device assembly 801 of FIG. 8. The placeholder removal and the optional gouging forms a second contact opening 910 that extends into the second S/D epitaxy 470 and effectively leaves in place the placeholder 450 beneath the first S/D epitaxy 460.

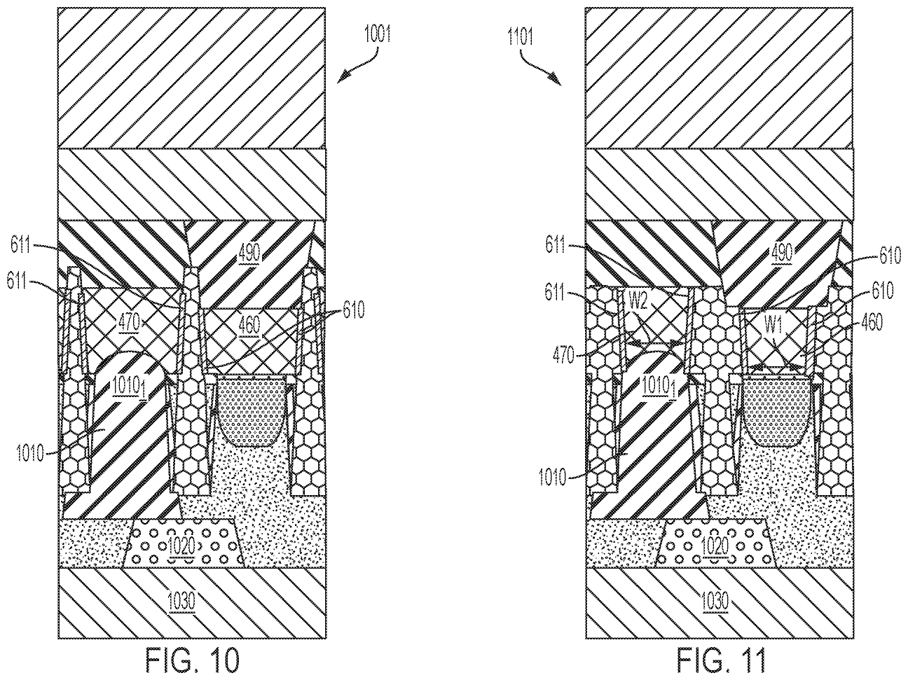

With continued reference to FIG. 9 and with additional reference to FIG. 10, a semiconductor device 1001 is provided in a final stage of being fabricated following backside contact formation to form backside contact 1010 and formations of a BPR 1020 and a BSPDN 1030 executed with respect to the semiconductor device assembly 901 of FIG. 9. As shown in FIG. 10, an upper end of the backside contact 1010 can be formed as a gouged contact 10101 and is disposed in contact with the second S/D epitaxy 470, the BPR 1020 is disposed in contact with a lower end of the backside contact 1010 and the BSPDN 1030 is disposed in contact with the BPR 1020.

The semiconductor device 1001 thus includes the first and second S/D epitaxy 460 and 470, the frontside contact 490 disposed in contact with the first S/D epitaxy 460 and the silicide 610, 611 which is formed along respective sides 461 (see FIGS. 6) and 471 (see FIG. 6) of each of the first and second S/D epitaxy 460 and 470, respectively. In addition, the semiconductor device 1001 is provided such that the silicide 610 at the first S/D epitaxy 460 is disposed in contact with the side 491 (see FIG. 6) of the frontside contact 490 and at least the side 461 of the first S/D epitaxy 460. In addition, the semiconductor device 1001 further includes the placeholder 450 (see FIG. 9) in contact with the first S/D epitaxy 460, the backside contact 1010, which is disposed in contact with the second S/D epitaxy 470 and which cuts through the STIs 440 (see FIG. 4), the BPR 1020 and the BSPDN 1030.

With reference to FIG. 11, a semiconductor device 1101 is provided and is similar to the semiconductor device 1010 of FIG. 10 except that, in semiconductor device 1101, the first and second S/D epitaxy 460 and 470 have been recessed by a selective epitaxial etch executed with respect to the semiconductor device assembly 501 of FIG. 5. This etch process results in the respective widths W1 and W2 of the first and second S/D epitaxy 460 and 470 being reduced from their original respective widths.

In these or other cases, at the first S/D epitaxy 460, the silicide 610 extends along at least the side 461 (see FIG. 6) of the first S/D epitaxy 460 and is in contact with a bottom portion of the side 491 (see FIG. 6) of the frontside contact 490 and the silicide 611 extends along the side 471 (see FIG. 6) of the second S/D epitaxy 470 and is in contact with a top of a side of the backside contact 1010. The silicide 610, 611 thus provides for improved and more reliable electrical contact between the frontside contact 490 and the first S/D epitaxy 460 and between the backside contact 1010 and the second S/D epitaxy 470.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device fabrication method, comprising:
executing front-end-of-line (FEOL) processing to form first and second source/drain (S/D) epitaxy;
forming a middle-of-line (MOL) contact to the first S/D epitaxy;
executing a self-aligned backside S/D cut to form an opening in which respective sides of each of the first and second S/D epitaxy are exposed;
depositing metallic material along the respective sides of each of the first and second S/D epitaxy in the opening; and
forming silicide from the metallic material whereby the silicide at the first S/D epitaxy contacts the MOL contact and the sides of the first S/D epitaxy.

2. The semiconductor device fabrication method according to claim 1, wherein the MOL contact is a gouged contact.

3. The semiconductor device fabrication method according to claim 1, further comprising executing a self-aligned backside cut toward the second S/D epitaxy.

4. The semiconductor device fabrication method according to claim 3, wherein the self-aligned backside cut comprises gouging into the second S/D epitaxy.

5. The semiconductor device fabrication method according to claim 3, further comprising executing backside contact metallization to form a backside contact in contact with the second S/D epitaxy.

6. The semiconductor device fabrication method according to claim 5, further comprising:
forming a backside power rail (BPR) in contact with the backside contact; and
forming a backside power distribution network (BSPDN) in contact with the BPR.

7. A semiconductor device fabrication method, comprising:
executing front-end-of-line (FEOL) processing to form first and second source/drain (S/D) epitaxy;
forming a middle-of-line (MOL) contact to the first S/D epitaxy;
executing a self-aligned backside S/D cut to form an opening in which respective sides of each of the first and second S/D epitaxy are exposed;
selectively etching the respective sides of each of the first and second S/D epitaxy to recess the respective sides of each of the first and second S/D epitaxy;
depositing metallic material along the respective sides of each of the first and second S/D epitaxy; and
forming silicide from the metallic material whereby the silicide at the first S/D epitaxy contacts the MOL contact and the sides of the first S/D epitaxy.

8. The semiconductor device fabrication method according to claim 7, wherein the MOL contact is a gouged contact.

9. The semiconductor device fabrication method according to claim 7, further comprising executing a self-aligned backside cut toward the second S/D epitaxy.

10. The semiconductor device fabrication method according to claim 9, wherein the self-aligned backside cut comprises gouging into the second S/D epitaxy.

11. The semiconductor device fabrication method according to claim 10, wherein:
the semiconductor device fabrication method further comprises executing backside contact metallization to form a backside contact in contact with the second S/D epitaxy, and
the silicide at the second S/D epitaxy contacts the backside contact and the sides of the second S/D epitaxy.

12. The semiconductor device fabrication method according to claim 11, further comprising:
forming a backside power rail (BPR) in contact with the backside contact; and
forming a backside power distribution network (BSPDN) in contact with the BPR.

13. A semiconductor device, comprising:
first and second source/drain (S/D) epitaxy;
a middle-of-line (MOL) contact disposed in contact with the first S/D epitaxy; and
silicide formed along respective sides of each of the first and second S/D epitaxy,
the silicide at the first S/D epitaxy being disposed in contact with the MOL contact and the sides of the first S/D epitaxy.

14. The semiconductor device according to claim 13, wherein the MOL contact is a gouged contact.

15. The semiconductor device according to claim 13, further comprising a backside placeholder element in contact with the first S/D epitaxy.

16. The semiconductor device according to claim 13, further comprising a backside contact disposed in contact with the second S/D epitaxy.

17. The semiconductor device according to claim 16, wherein the backside contact is a gouged contact.

18. The semiconductor device according to claim 16, wherein the backside contact cuts through shallow trench isolation (STI).

19. The semiconductor device according to claim 16, wherein:
the respective sides of each of the first and second S/D epitaxy are recessed from an original width, and
the silicide at the second S/D epitaxy is disposed in contact with the backside contact and the sides of the second S/D epitaxy.

20. The semiconductor device according to claim 16, further comprising:
a backside power rail (BPR) disposed in contact with the backside contact; and
a backside power delivery network (BSPDN) disposed in contact with the BPR.
